(19) United States
(12) Patent Application Publication
(10) Pub. No.: US 2013/0327368 A1
(43) Pub. Date: Dec. 12, 2013

(54) CROSSMEMBER THERMOELECTRIC GENERATOR WITH IMPROVED THERMAL EXPANSION PROTECTION

(71) Applicant: Gentherm Incorporated, Northville, MI (US)

(72) Inventor: Douglas T. Crane, Altadena, CA (US)

(21) Appl. No.: 13/912,001

(22) Filed: Jun. 6, 2013

Related U.S. Application Data
(60) Provisional application No. 61/656,903, filed on Jun. 7, 2012.

(51) Int. Cl. H01L 35/32

(52) U.S. Cl. CPC H01L 35/32
USPC 136/201; 136/224

(57) ABSTRACT

A thermoelectric system includes a plurality of cold-side conduits extending parallel to one another along a first direction and configured to have a first working fluid flowing therethrough. Each cold-side conduit includes a cold-side tube and a plurality of cold-side shunts in thermal communication with the cold-side tube. The system further includes a plurality of hot-side conduits extending parallel to one another along a second direction and configured to have a second working fluid flowing therethrough. The second direction is perpendicular to the first direction. Each hot-side conduit includes a hot-side tube and a plurality of hot-side shunts in thermal communication with the hot-side tube. The system further includes a plurality of thermoelectric stacks. Each thermoelectric stack of the plurality of thermoelectric stacks extends along a third direction and is configured to have electrical current flow through the thermoelectric stack along the third direction.

### CROSS-REFERENCE TO RELATED APPLICATIONS

This application claims the benefit of U.S. Provisional Application No. 61/656,903 filed Jun. 7, 2012, which is incorporated herein in its entirety by reference.

### BACKGROUND

1. Field of the Application

The present application relates generally to thermoelectric cooling, heating, and power generation systems.

2. Description of the Related Art

Thermoelectric (TE) devices and systems can be operated in either heating/cooling or power generation modes. In the former, electric current is passed through a TE device to pump the heat from the cold side to the hot side. In the latter, a heat flux driven by a temperature gradient across a TE device is converted into electricity. In both modalities, the performance of the TE device is largely determined by the figure of merit of the TE material and by the parasitic (dissipative) losses throughout the system. Working elements in the TE device are typically p-type and n-type semiconducting materials. Mechanical properties of these materials can be brittle with a common mode of failure of TE devices being cracking of the elements caused by the shear loads on the elements.

One of the concerns in thermoelectric generator (TEG) design is thermal expansion management. Hot sides of TEGs can be exposed to temperatures as high as 600° C. in automotive applications (e.g., exhaust, catalytic converters, etc.) and can see temperatures up to 1000° C. in other applications such as radioisotope thermoelectric generators (RTGs). TEGs also have a cold side which in some applications can be 500° C. lower relative to the hot side. The cold side is also positioned in close proximity to the hot side in a TEG. For example, in some high power density applications, the desire is to have thermoelectric (TE) elements (positioned between the hot and cold sides of the TEG) less than or equal to 5 mm in either height and/or thickness, and/or to have a temperature gradient less than or equal to 100 C/mm. A large temperature difference (e.g., 500° C.) between the hot and cold sides of the TEGs and/or the close proximity of the hot and cold sides of the TEGs can cause a large thermal expansion mismatch. In certain designs, this thermal expansion mismatch must then be maintained by the often brittle TE elements. If not managed properly, the TE elements will be ripped apart or fail during operation of the TEG.

### SUMMARY

Certain embodiments described herein provide a thermoelectric system comprising a plurality of cold-side conduits extending parallel to one another along a first direction and configured to have a first working fluid flowing therethrough. Each cold-side conduit of the plurality of cold-side conduits comprises a cold-side tube and a plurality of cold-side shunts in thermal communication with the cold-side tube. The thermoelectric system further comprises a plurality of hot-side conduits extending parallel to one another along a second direction and configured to have a second working fluid flowing therethrough. The second direction is perpendicular to the first direction. Each hot-side conduit of the plurality of hot-side conduits comprises a hot-side tube and a plurality of hot-side shunts in thermal communication with the hot-side tube. The thermoelectric system further comprises a plurality of thermoelectric stacks. Each thermoelectric stack of the plurality of thermoelectric stacks comprises a plurality of thermoelectric elements, a first plurality of cold-side shunts of a first cold-side conduit, a first hot-side shunt of a first hot-side conduit, and a second hot-side shunt of a second hot-side conduit. Each thermoelectric stack of the plurality of thermoelectric stacks extends along a third direction and is configured to have electrical current flow through the thermoelectric stack along the third direction.

Certain embodiments described herein provide a thermoelectric system comprising a plurality of cold-side heat exchangers extending parallel to one another along a first direction. Each cold-side heat exchanger of the plurality of cold-side heat exchangers comprises a cold-side member and a plurality of cold-side shunts in thermal communication with the cold-side member. The thermoelectric system further comprises a plurality of hot-side heat exchangers extending parallel to one another along a second direction. The second direction is perpendicular to the first direction. Each hot-side heat exchanger of the plurality of hot-side heat exchangers comprises a hot-side member and a plurality of hot-side shunts in thermal communication with the hot-side member. The thermoelectric system further comprises a plurality of thermoelectric stacks. Each thermoelectric stack of the plurality of thermoelectric stacks comprises a plurality of thermoelectric elements, a first plurality of cold-side shunts of a first cold-side heat exchanger, a first hot-side shunt of a first hot-side heat exchanger, and a second hot-side shunt of a second hot-side heat exchanger. Each thermoelectric stack of the plurality of thermoelectric stacks extends along a third direction and is configured to have electrical current flow through the thermoelectric stack along the third direction.

Certain embodiments described herein provide a method of managing thermal expansion during operation of a thermoelectric system. The method comprises flowing a first working fluid through a plurality of cold-side conduits extending parallel to one another along a first direction. The method further comprises flowing a second working fluid through a plurality of hot-side conduits extending parallel to one another along a second direction. The method further comprises flowing electrical current through a plurality of thermoelectric stacks extending parallel to one another along a third direction that is either parallel or perpendicular to at least one of the first direction and the second direction. Each thermoelectric stack of the plurality of thermoelectric stacks comprises a plurality of thermoelectric elements in thermal communication with the plurality of cold-side conduits and the plurality of hot-side conduits.

The paragraphs above recite various features and configurations of one or more of a thermoelectric assembly, a thermoelectric module, or a thermoelectric system, that have been contemplated by the inventors. It is to be understood that the inventors have also contemplated thermoelectric assemblies, thermoelectric modules, and thermoelectric systems which comprise combinations of these features and configurations from the above paragraphs, as well as thermoelectric assemblies, thermoelectric modules, and thermoelectric systems which comprise combinations of these features and configurations from the above paragraphs with other features and configurations disclosed in the following paragraphs.

### BRIEF DESCRIPTION OF THE DRAWINGS

Various embodiments are depicted in the accompanying drawings for illustrative purposes, and should in no way be interpreted as limiting the scope of the thermoelectric devices, systems, or methods described herein. In addition, various features of different disclosed embodiments can be combined with one another to form additional embodiments, which are part of this disclosure. Any feature or structure can be removed, altered, or omitted. Throughout the drawings, reference numbers may be reused to indicate correspondence between reference elements.

FIG. 1A schematically illustrates a perspective view of an example thermoelectric system comprising a plurality of cold-side and hot-side conduits in accordance with certain embodiments described herein.

FIG. 1B schematically illustrates a front view of the example thermoelectric system of FIG. 1A.

FIG. 1C schematically illustrates a top view of the example thermoelectric system of FIG. 1A.

FIG. 2A schematically illustrates a perspective view of another example thermoelectric system comprising a plurality of cold-side and hot-side conduits in accordance with certain embodiments described herein.

FIG. 2B schematically illustrates a front view of the example thermoelectric system of FIG. 2A.

FIG. 2C schematically illustrates a top view of the example thermoelectric system of FIG. 2A.

FIG. 3A schematically illustrates a perspective view of another example thermoelectric system comprising a plurality of cold-side and hot-side conduits in accordance with certain embodiments described herein.

FIG. 3B schematically illustrates a front view of the example thermoelectric system of FIG. 3A.

FIG. 3C schematically illustrates a top view of the example thermoelectric system of FIG. 3A.

FIG. 4 schematically illustrates a perspective view of the example TE system of FIG. 1A incorporated into a full-scale TEG system in accordance with certain embodiments described herein.

FIG. 5 schematically illustrates the example system of FIG. 4 comprising an outer housing in accordance with certain embodiments described herein.

FIG. 6 schematically illustrates a partial section view of the example system of FIG. 5 in accordance with certain embodiments described herein.

FIG. 7A schematically illustrates a partial view of the example system of FIG. 4 in accordance with certain embodiments described herein.

FIG. 7B schematically illustrates a partial side view of the example system of FIG. 7A.

FIG. 7C schematically illustrates a partial top view of the example system of FIG. 7A.

FIG. 8A schematically illustrates shunts encircling cylindrical hot-side conduits in accordance with certain embodiments described herein.

FIG. 8B schematically illustrates shunts bonded to the top and bottom of rectangular cross section hot-side conduits in accordance with certain embodiments described herein.

FIG. 9 schematically illustrates an example hot-side conduit subassembly in accordance with certain embodiments described herein.

FIG. 10 schematically illustrates an example cold-side conduit subassembly in accordance with certain embodiments described herein.

FIG. 11 schematically illustrates a partial section view of an example system comprising stacked hot and cold-side conduit subassemblies on a rod base in accordance with certain embodiments described herein.

FIGS. 12A-12B schematically illustrate partial perspective and bottom views of the system of FIG. 11 in accordance with certain embodiments described herein.

FIG. 13 is a generalized block flowchart of an example method in accordance with certain embodiments described herein.

### DETAILED DESCRIPTION

A thermoelectric system as described herein can be a thermoelectric generator (TEG) which uses the temperature difference between two fluids, two solids (e.g., rods), or a solid and a fluid to produce electrical power via thermoelectric materials. Alternatively, a thermoelectric system as described herein can be a heater, cooler, or both which serves as a solid state heat pump used to move heat from one surface to another, thereby creating a temperature difference between the two surfaces via the thermoelectric materials. Each of the surfaces can be in thermal communication with or comprise a solid, a liquid, a gas, or a combination of two or more of a solid, a liquid, and a gas, and the two surfaces can both be in thermal communication with a solid, both be in thermal communication with a liquid, both be in thermal communication with a gas, or one can be in thermal communication with a material selected from a solid, a liquid, and a gas, and the other can be in thermal communication with a material selected from the other two of a solid, a liquid, and a gas.

The thermoelectric system can include a single thermoelectric assembly or a group of thermoelectric assemblies) depending on usage, power output, heating/cooling capacity, coefficient of performance (COP) or voltage. Although the examples described herein may be described in connection with either a power generator or a heating/cooling system, the described features can be utilized with either a power generator or a heating/cooling system.

Because the thermoelectric assembly and/or thermoelectric system may be exposed to significant temperature differences (for example, up to 500° C.), there are many features described herein which allow for thermal expansion and stress relief on the portions of the thermoelectric assemblies.

The term “thermal communication” is used herein in its broad and ordinary sense, describing two or more components that are configured to allow heat transfer from one component to another. For example, such thermal communication can be achieved, without loss of generality, by snug contact between surfaces at an interface; one or more heat transfer materials or devices between surfaces; a connection between solid surfaces using a thermally conductive material system, wherein such a system can include pads, thermal grease, paste, one or more working fluids, or other structures with high thermal conductivity between the surfaces (e.g., heat exchangers); other suitable structures; or combinations of structures. Substantial thermal communication can take place between surfaces that are directly connected (e.g., contact each other) or indirectly connected via one or more interface materials.

As used herein, the terms “shunt” and “heat exchanger” have their broadest reasonable interpretation, including but not limited to a component (e.g., a thermally conductive device or material) that allows heat to flow from one portion of the component to another portion of the component. Shunts can be in thermal communication with one or more thermoelectric materials (e.g., one or more thermoelectric elements) and in thermal communication with one or more heat exchangers of the thermoelectric assembly or system. Shunts described herein can also be electrically conductive and in electrical communication with the one or more thermoelectric materials so as to also allow electrical current to flow from one portion of the shunt to another portion of the shunt (e.g., thereby providing electrical communication between multiple thermoelectric materials or elements). Heat exchangers (e.g., tubes and/or conduits) can be in thermal communication with the one or more shunts and one or more working fluids of the thermoelectric assembly or system. Various configurations of one or more shunts and one or more heat exchangers can be used (e.g., one or more shunts and one or more heat exchangers can be portions of the same unitary element, one or more shunts can be in electrical communication with one or more heat exchangers, one or more shunts can be electrically isolated from one or more heat exchangers, one or more shunts can be in direct thermal communication with the thermoelectric elements, one or more shunts can be in direct thermal communication with the one or more heat exchangers, an intervening material can be positioned between the one or more shunts and the one or more heat exchangers). Furthermore, as used herein, the words “cold,” “hot,” “cooler,” “hotter” and the like are relative terms, and do not signify a particular temperature or temperature range.

There are various ways to manage thermal expansion mismatch, such as with liquid joints. For example, TEGs use thermal grease and/or liquid metal in combination with a complex cold shunt subassembly to overcome thermal expansion mismatch with adequate thermal and electrical contact. However, this can be less than ideal for maintaining the TE parts or materials in consistent operating condition. Certain embodiments disclosed herein potentially eliminate the need for both thermal grease and liquid metal.

Another desirable factor in TEG design is to have electrical and thermal contact resistances as low as possible. This factor can be at odds with managing thermal expansion mismatch because thermal expansion mismatch can often cause the hot side of a TEG to separate further from the cold side resulting in increased interfacial resistance. Certain embodiments described herein, address thermal expansion mismatch between the hot and cold sides of the TEG while still maintaining low electrical and thermal contact resistances.

For automotive as well as other applications, it can be desirable to have the voltage of a device providing power be at a certain level. In an automotive case, nominal voltage may be 14V. A cylindrical TEG has been developed that takes advantage of the hoop stress of a thermally expanding cylinder inside of a ring shunt in order to improve thermal contact as disclosed in U.S. Patent Publication No. 2011/0067742 and incorporated by reference herein. To take advantage of the hoop stress, the ring is a solid or split ring. In order to accommodate large mass flows while keeping pressure drop at a minimum, diameters of the cylindrical TEGs are relatively large, resulting in many parallel connections of the TE couples.

These multiple parallel connections can lead to very high current and very low voltage for the device. A power converter can be added to the system to increase the voltage and reduce current, but this adds additional cost and takes up valuable package space, and decreases efficiency. Certain embodiments described herein increase voltage and reduce current with more parallel/series flexibility. This design flexibility can allow certain TEG embodiments described herein to fit many different applications and package spaces.

In many TEG applications, particularly those involving a gas side, it can be very important to manage the pressure drop across the heat exchangers. In the automotive application, high pressure drop across the hot side heat exchanger of a TEG can cause excessive backpressure in the exhaust system of the vehicle. This excessive backpressure can reduce the performance of the vehicle's engine or even damage it. In other applications, high pressure drop may lead to the need for high fan or pump power which can decrease the net power output of the TEG device. The cross flow nature of certain embodiments described herein allow more flexibility to combat high pressure drop.

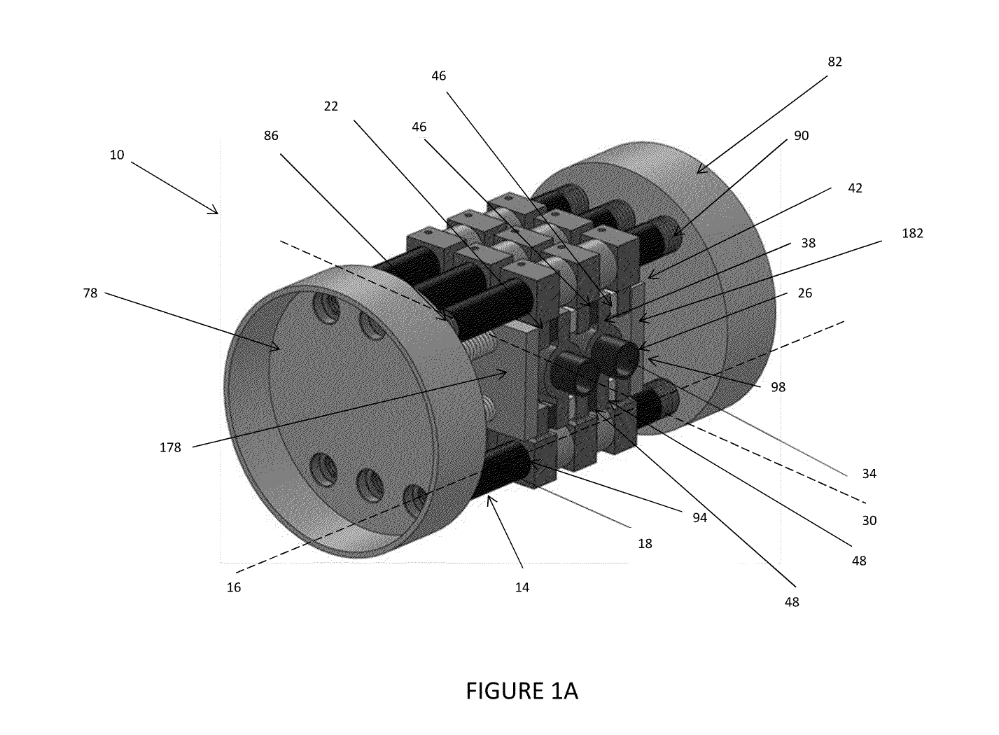

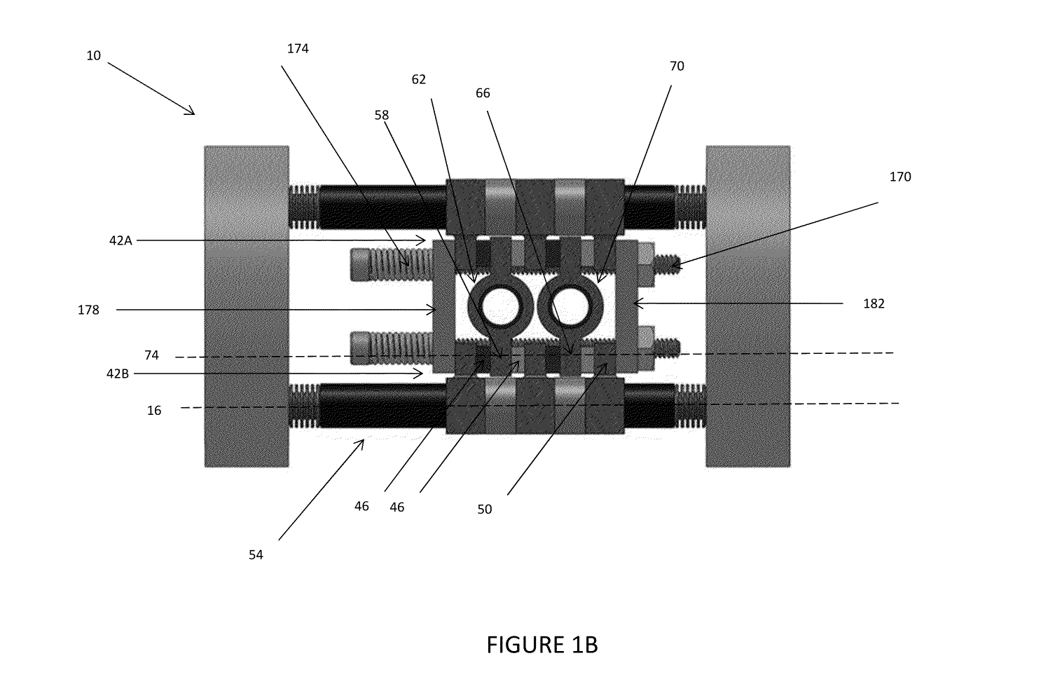

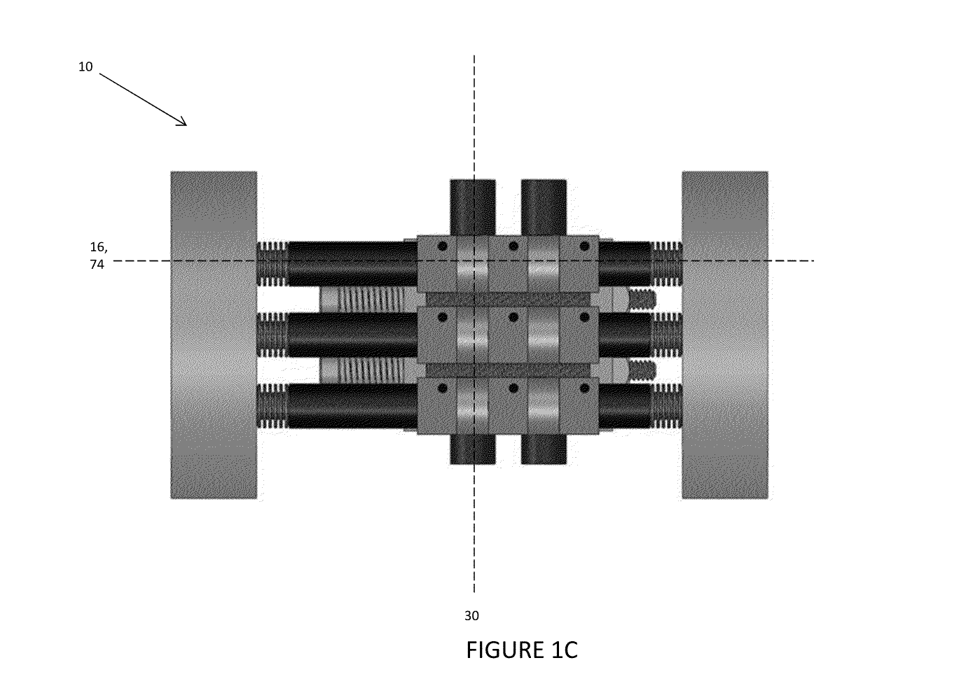

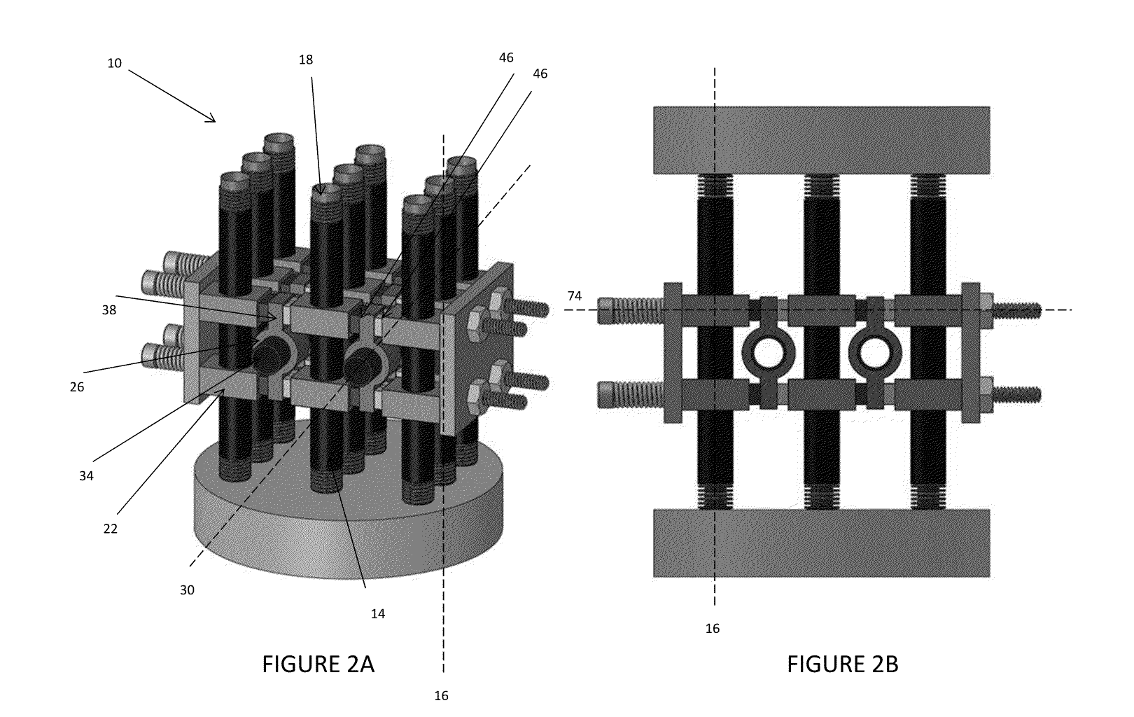

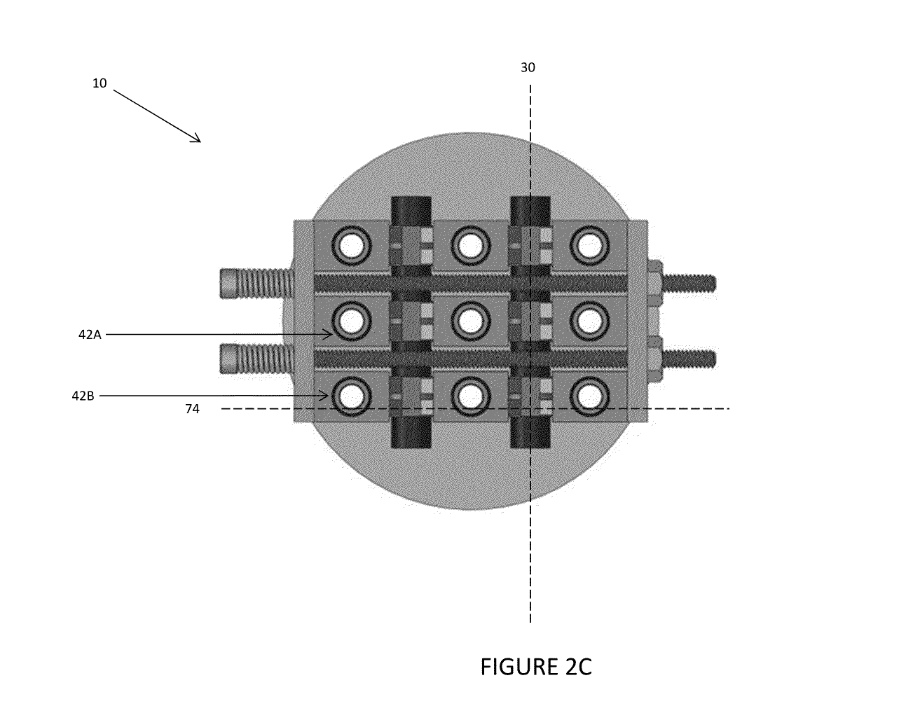

FIGS. 1A-1C and 2A-2C schematically illustrate example thermoelectric (TE) systems 10 in accordance with certain embodiments described herein. In some embodiments, TE system 10 comprises a plurality of cold-side heat exchangers (e.g., cold-side conduits 14) extending parallel to one another along a first direction (indicated by the broken line 16). Each cold-side heat exchanger of the plurality of cold-side heat exchangers comprising a cold-side member (e.g., cold-side rod or tube 18) and a plurality of cold-side shunts 22 in thermal communication with the cold-side member. The TE system 10 further comprises a plurality of hot-side heat exchangers (e.g., hot-side conduits 26) extending parallel to one another along a second direction (indicated by the broken line 30). The second direction is perpendicular to the first direction. Each hot-side exchanger of the plurality of hot-side heat exchanger comprises a hot-side member (e.g., hot-side rod or tube 34) and a plurality of hot-side shunts 38 in thermal communication with the hot-side heat member. The TE system 10 further comprises a plurality of thermoelectric stacks 42. Each TE stack of the plurality of TE stacks 42 comprises a plurality of thermoelectric elements 46 (e.g., including p-type and n-type TE elements), a first plurality of cold-side shunts 50 of a first cold-side heat exchanger, a first hot-side shunt 58 of a first hot-side heat exchanger, and a second hot-side shunt 66 of a second hot-side heat exchanger, each thermoelectric stack of the plurality of thermoelectric stacks 42 extending along a third direction (indicated by the broken line 74) and configured to have electrical current flow through the thermoelectric stack along the third direction.

In certain embodiments, the TE system 10 comprises a plurality of cold-side conduits 14 extending parallel to one another along a first direction (indicated by the broken line 16). The plurality of cold-side conduits 14 are configured to have a first working fluid flowing therethrough. Each cold-side conduit of the plurality of cold-side conduits 14 comprises a cold-side tube 18 and a plurality of cold-side shunts 22 in thermal communication with the cold-side tube 18. The TE system 10 further comprises a plurality of hot-side conduits 26 extending parallel to one another along a second direction (indicated by the broken line 30). The plurality of hot-side conduits 26 are configured to have a second working fluid flowing therethrough. The second direction is perpendicular to the first direction. Each hot-side conduit of the plurality of hot-side conduits 26 comprises a hot-side tube 34 and a plurality of hot-side shunts 38 in thermal communication with the hot-side tube 34. The TE system 10 further comprises a plurality of thermoelectric stacks 42. Each TE stack of the plurality of TE stacks 42 comprises a plurality of thermoelectric elements 46 (e.g., including p-type and n-type TE elements), a first plurality of cold-side shunts 50 of a first cold-side conduit 54, a first hot-side shunt 58 of a first hot-side conduit 62, and a second hot-side shunt 66 of a second hot-side conduit 70, each thermoelectric stack of the plurality of thermoelectric stacks 42 extending along a third direction (indicated by the broken line 74) and configured to have electrical current flow through the thermoelectric stack along the third direction.

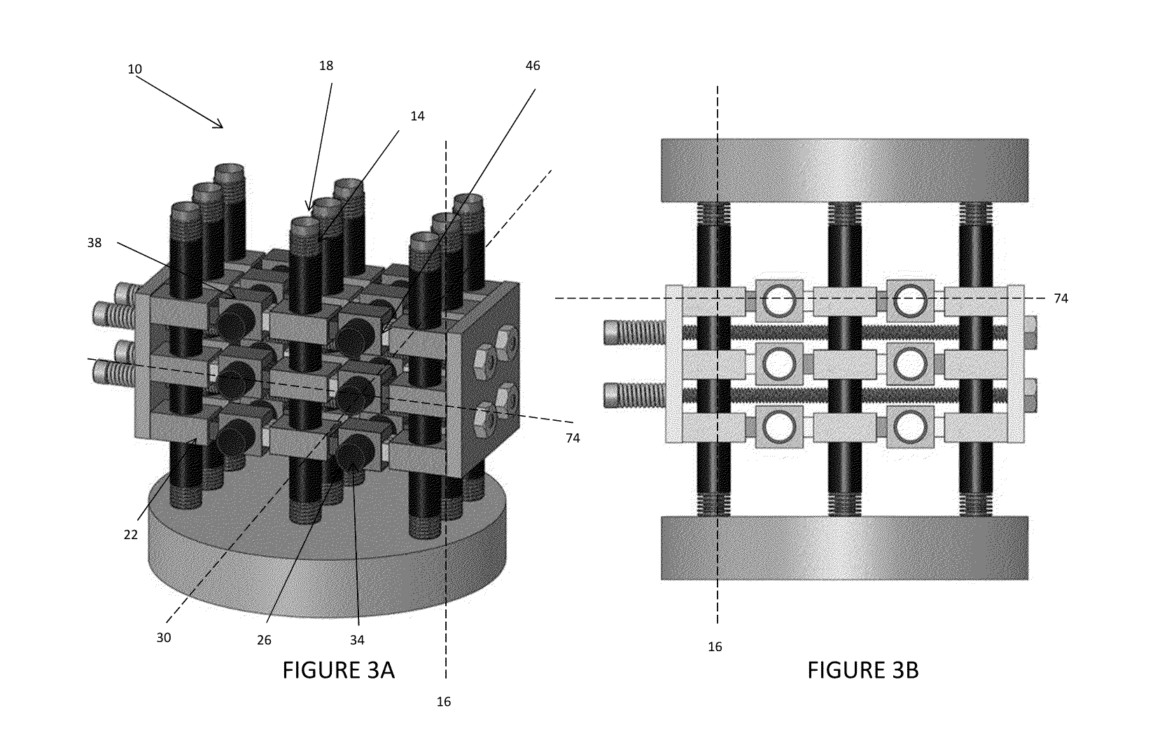

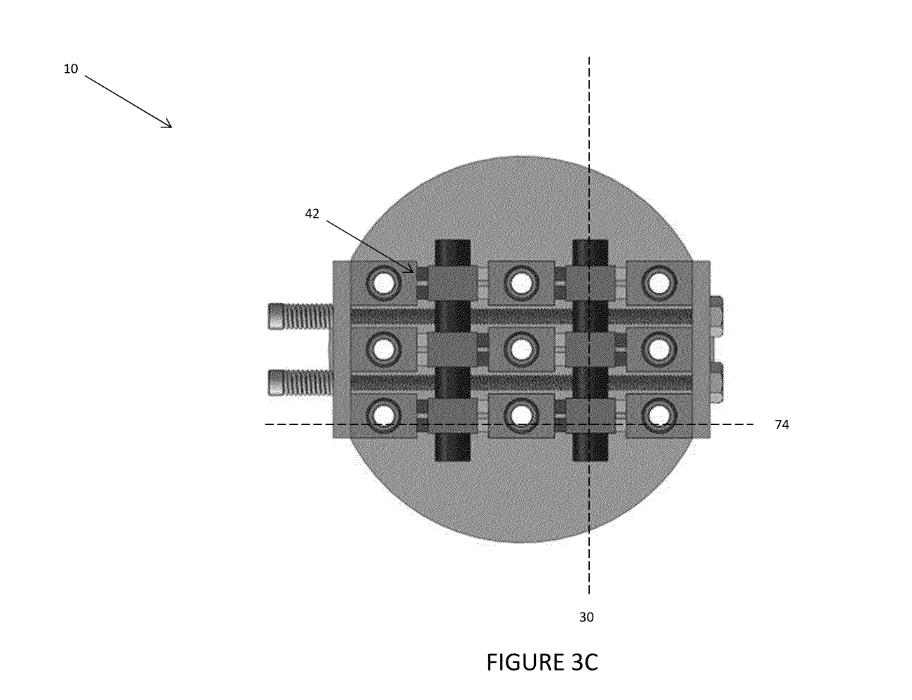

In certain embodiments as described herein, the TE elements 46, the cold-side shunts 22, and the hot-side shunts 38 are arranged in a “stacked” configuration in which p-type and n-type TE elements 46 alternate with one another and are in electrical communication with one another via the cold-side shunts 22 and the hot-side shunts 38 which are sandwiched between adjacent p-type and n-type TE elements 46 such that electrical current (and/or voltage, power) can flow generally along a single direction through the TE elements 46, the cold-side shunts 22, and the hot-side shunts 38 (e.g., generally parallel directions through the TE elements and the shunts). For example, as illustrated in FIGS. 1A-1C, the TE system 10 uses the stacked configuration in which the stacks extend axially along a direction parallel to the cold-side tubes 18 (the third direction is parallel to the first direction). In FIGS. 3A-3C, the stacks extend in a direction that is perpendicular to the hot-side tubes 34 and the cold-side tubes 18 (the third direction is perpendicular to the first direction and to the second direction).

Hot-side tubes 34 in FIGS. 1A-1C, 2A-2C, and 3A-3C run perpendicular to cold-side tubes 18. In FIGS. 1A-1C and 2A-2C, heat flux is transferred in two directions (e.g., extending opposite to each other) from the hot-side tubes 34 by the hot-side shunts 38 which extend in the two directions. In FIGS. 3A-3C, the hot-side shunts 38 and the hot-side tubes 34 are within the stack and transfer heat flux within the stack. In FIGS. 1A-1C, each cold-side shunt 22 extends from the corresponding stack in one direction. In FIGS. 2A-2C and 3A-3C, the cold-side shunts and the cold-side tubes are within the stack and transfer heat flux within the stack. For example, as illustrated in FIGS. 1B and 2B, in some embodiments, each hot-side conduit 62, 70 of the plurality of hot-side conduits 26 is in thermal communication with two thermoelectric stacks of the plurality of thermoelectric stacks 42.

As discussed herein, a “stonehenge” configuration refers to when the TE elements and the shunts are arranged in which p-type and n-type TE elements alternate with one another and are in electrical communication with one another via shunts which are alternately positioned on a hot side of the TE elements and a cold side of the TE elements such that electrical current can flow serially through the TE elements and the shunts in a serpentine fashion (e.g., vertically through the TE elements and horizontally through the shunts).

In some embodiments, the third direction is parallel to the first direction as illustrated in FIG. 1B. In other embodiments, as illustrated in FIGS. 2A-2C, the third direction is perpendicular to the first direction and perpendicular to the second direction. In some embodiments, the first direction is non-perpendicular and/or non-parallel to the second direction (e.g., between 0 and 90 degrees). In some embodiments the second direction is non-perpendicular and/or non-parallel to the third direction. In some embodiments the first direction is non-perpendicular and/or non-parallel to the third direction.

TEGs are made of often brittle semiconductor material and are comprised of many parts and many solder connections. When placed in a high shock and vibration environment, such as an automotive application, the TEG is highly susceptible to premature failure due to shock and vibration. The use of bellows as further described herein may help isolate the TEG device from such a detrimental environment, but configurations without bellows are also in accordance with certain embodiments described herein.

As schematically illustrated in FIGS. 1A-3C, in some embodiments, the thermoelectric system 10 is configured such that each cold-side conduit of the plurality of cold-side conduits 14 is in fluidic-communication with an inlet cold-side manifold 78 and an outlet cold-side manifold 82, wherein each cold-side conduit of the plurality of cold-side conduits 14 comprises at least a first bellows portion 86 mechanically coupled to the inlet cold-side manifold 78 and a second bellows portion 90 mechanically coupled to the outlet cold-side manifold 82. In certain configurations, bellows coupled to the manifolds at the end of each cold-side conduit of the plurality of cold-side conduits 14 can accommodate (e.g., absorb) movement (e.g., axial, radial) due to thermal expansion of the hot-side tubes 34. The hot-side tubes 34 are rigidly connected to their respective manifolds (not shown), which are similar to manifolds for a shell and tube heat exchanger. A similar manifold can be used for the cold-side tubes and/or conduits. In some embodiments, the respective bellow portions 86, 90 are rigidly attached to the cold-side manifolds 78, 82. The use of bellows on the cold-side tube ends will also help to isolate the TE couples from severe shock and vibration that might be experienced during certain applications. Certain embodiments described herein do not utilize the bellows portions.

In some embodiments, as illustrated in FIGS. 1A-3C, each cold-side shunt of the plurality of cold-side shunts 22 can comprise at least one hole 94 configured to allow a thermally conductive medium (not shown) to be applied between the cold-side shunt 22 and the cold-side tube 18. Such holes may be used to more directly apply a thermally conductive medium between the cold-side shunts and the cold-side tubes. This medium can be thermal grease or some other thermal interface material (e.g., braze or solder paste). In certain embodiments, each hot-side shunt can comprise at least one hole configured to allow a thermally conductive medium (e.g., thermal grease) to be applied between the hot-side shunt and the hot-side tube.

Non-rigid bonds have been another way to accommodate thermal expansion mismatch. These non-rigid bonds can be positioned at interfaces between the heat exchangers and their associated shunts of a TEG. To maintain low contact resistance for these interfaces, tight tolerances on dimensions of the components of the TEG have previously been used. Such tight tolerances are not desirable from a manufacturing and subsequent cost standpoint. Certain embodiments described herein have rigid bonds between shunts 22, 38 and heat exchangers (e.g., tubes 18, 34 and/or conduits 14, 26) on at least one of the hot side, the cold side, or both. Hot-side shunts 38 and cold-side shunts 22 can be rigidly connected to the hot-side tubes 34 and cold-side tubes 18 respectively. With rigid bonds between the shunts 22, 38 and the corresponding heat exchangers, the need for such tight tolerances can be significantly reduced. There is also a reduction in contact resistance with such a configuration.

In certain embodiments, as illustrated in FIGS. 1A-1C, the plurality of cold-side conduits 14 are arranged in an array of cold-side conduits 14 with the cold-side conduits 14 of the array arranged in at least two cold-side planes that are parallel to one another. The plurality of hot-side conduits 26 are arranged in an array of hot-side conduits 26 with the hot-side conduits 26 of the array arranged in at least one hot-side plane that is parallel to and between a corresponding pair of cold-side planes of the at least two cold-side planes. The TE system 10 further comprises a first plurality of thermoelectric elements 46 (e.g., in at least one first TE stack). Each thermoelectric element of the first plurality of thermoelectric elements 46 is sandwiched between a hot-side shunt 38 of a hot-side plane of the at least one hot-side plane and a cold-side shunt 22 of a first cold-side plane of the corresponding pair of cold-side planes. The TE system 10 comprises a second plurality of thermoelectric elements 48 (e.g., in at least one second TE stack). Each thermoelectric element of the second plurality of thermoelectric elements 48 is sandwiched between a hot-side shunt 38 of the hot-side plane and a cold-side shunt 22 of a second cold-side plane of the corresponding pair of cold-side planes.

In certain embodiments, as shown in FIGS. 1A-1C, the first plurality of thermoelectric elements 46 are arranged in a plurality of first thermoelectric stacks 42A. Each first thermoelectric stack of the plurality of first thermoelectric stacks 42A comprises the plurality of cold-side shunts 22 of one cold-side conduit 14 of the first cold-side plane and one hot-side shunt 38 from each hot-side conduit 26 of the hot-side plane. In certain embodiments, the second plurality of thermoelectric elements 48 are arranged in a plurality of second thermoelectric stacks 42B. Each second thermoelectric stack of the plurality of second thermoelectric stacks 42B comprises the plurality of cold-side shunts 22 of one cold-side conduit 14 of the second cold-side plane and one hot-side shunt 38 from each hot-side conduit 26 of the hot-side plane.

FIGS. 2A-2C schematically illustrate an alternative configuration of thermoelectric system 10 from that of FIGS. 1A-1C. In FIGS. 1A-1C, the hot-side plane is parallel to and between a corresponding pair of cold-side planes. In FIGS. 2A-2C, the hot-side plane is perpendicular to the cold-side planes. In FIGS. 1A-1C, the hot and cold-side tubes 34, 18 are perpendicular to each other and electrical current flow through the TE stacks is in planes that are separate and parallel to the cold-side planes and the hot-side plane. In FIGS. 2A-2C, electrical current flows through the TE stacks in planes that are perpendicular to the at least one of the cold-side planes and the hot-side plane. In FIGS. 1A-1C and 2A-2C, each of the hot fluid flow, cold fluid flow, and electrical current flow run in separate planes from one another. In some embodiments, the configuration of FIGS. 2A-2C may provide an improvement in thermal expansion management in the radial direction over the configuration illustrated in FIGS. 1A-1C because the cold-side tubes 18 can also move or flex to accommodate radial as well as axial thermal expansion of the hot-side tubes 34.

From a flow perspective, FIGS. 1A-1C show a configuration in having cold fluid flow in a direction perpendicular to the direction of hot fluid flow and parallel to the direction of TE electrical current flow. In FIGS. 2A-2C and 3A-3C, all the respective flows are in directions perpendicular to one another.

In certain embodiments, as shown in FIGS. 2A-2C, the plurality of thermoelectric elements 46 are arranged in a plurality of thermoelectric stacks. A first thermoelectric stack 42A of the plurality of thermoelectric stacks comprises one cold-side shunt 22 of each cold-side conduit of a first cold-side plane and one hot-side shunt 38 from each hot-side conduit 26 of a first hot-side plane. In certain embodiments, a second thermoelectric stack 42B of the plurality of thermoelectric stacks comprises one cold-side shunt 22 of each cold-side conduit of a second cold-side plane and one hot-side shunt 38 from each hot-side conduit 26 of the first hot-side plane.

As described above, the interfacial resistances inherent in many TEG designs can be very detrimental to getting the heat and electrical current into and out of the TE elements. Certain embodiments described herein allow more surface area for TE element placement than some other TEG designs. While certain such designs may use more costly TE materials than other designs, a benefit is that the heat flow is spread over more TEs. This configuration can reduce the impact of harmful contact resistances and can allow the TEG to perform at a higher power output. FIGS. 3A-3C schematically illustrate a TE system 10 that utilizes space more efficiently. The shunts can be a cross between and/or combination of traditional “stonehenge” shunts and the “T” shunts of the stacked design (e.g., the shunts are not “T” shunts and not serpentine “stonehenge” shunts). Depending on the design, the thermal resistance of these shunts can be lower than those of the “T” shunts but the electrical resistance higher.

FIGS. 3A-3C schematically illustrate a thermoelectric system 10 comprising an array of cold-side conduits 14 extending parallel to one another along a first direction (indicated by the broken line 16) and configured to have a first working fluid flowing therethrough. The cold-side conduits 14 are arranged in a plurality of cold-side planes that are parallel to one another. The TE system 10 comprises an array of hot-side conduits 26 extending parallel to one another along a second direction (indicated by the broken line 30) and configured to have a second working fluid flowing therethrough. The second direction is perpendicular to the first direction. The hot-side conduits 26 are arranged in a plurality of hot-side planes that are parallel to one another, parallel to the cold-side planes, and interleaved with the cold-side planes. The hot fluid (e.g., second working fluid) flows in a direction perpendicular to the direction of the cold fluid (e.g., first working fluid) flow. The hot fluid and the cold fluid flow in a direction perpendicular to the TE electrical current flow through the TE stacks. The TE system 10 further comprises a plurality of thermoelectric elements 46, wherein each thermoelectric element of the plurality of thermoelectric elements 46 is sandwiched between adjacent planes of the plurality of cold-side planes and the plurality of hot-side planes.

In certain embodiments, the plurality of thermoelectric elements 46 are arranged in a plurality of thermoelectric stacks 42. Each thermoelectric stack of the plurality of thermoelectric stacks 42 comprises a cold-side conduit 14 from each cold-side plane of the plurality of cold-side planes and a hot-side conduit 26 from each hot-side plane of the plurality of hot-side planes. In certain embodiments, each thermoelectric stack of the plurality of thermoelectric stacks 42 extends along a third direction (indicated by the broken line 74) perpendicular to the first direction and perpendicular to the second direction.

In certain embodiments, each cold-side conduit of the array of cold-side conduits 14 comprises a cold-side tube 18 and a plurality of cold-side shunts 22 in thermal communication with the cold-side tube 18. Each hot-side conduit of the array of hot-side conduits 26 comprises a hot-side tube 34 and a plurality of hot-side shunts 38 in thermal communication with the hot-side tube 34, wherein each thermoelectric element of the plurality of thermoelectric elements 46 is sandwiched between a cold-side shunt 22 of a cold-side plane and a hot-side shunt 38 of a hot-side plane adjacent to the cold-side plane.

In certain embodiments, each thermoelectric stack of the plurality of thermoelectric stacks 42 is intersected by the cold-side tubes 18 of the thermoelectric stack. In certain embodiments, each thermoelectric stack of the plurality of thermoelectric stacks 42 is intersected by the hot-side tubes 34 of the thermoelectric stack.

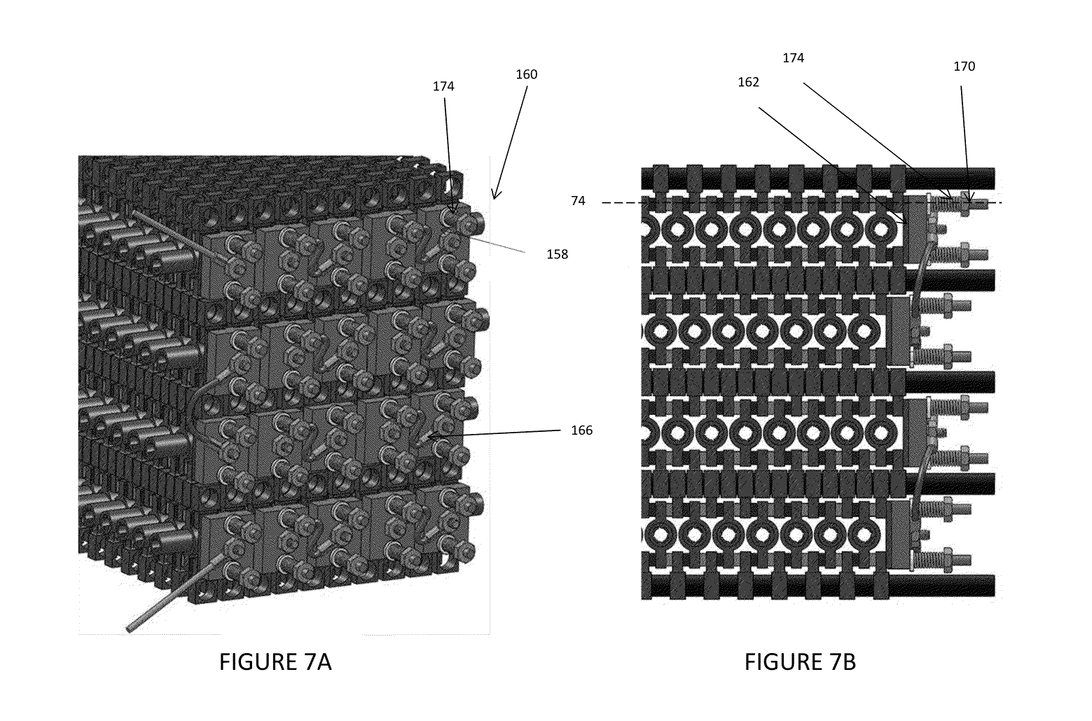

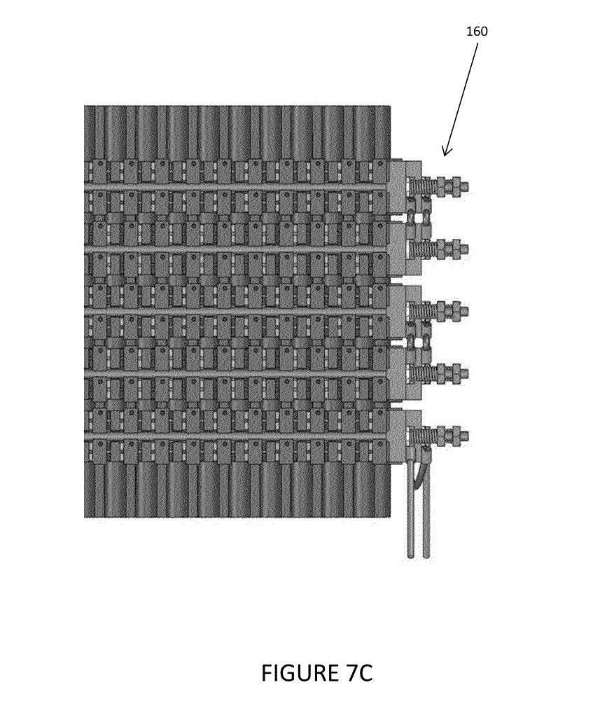

In some embodiments, TE couples or stacks do not have internal springs (e.g., springs between adjacent TE couples or shunts). Springs can be positioned at the end of each row of couples on the cold-side as discussed with regard to FIGS. 7A-7C. Shunts can be rigidly bonded to the heat exchanger tubes on both the hot and cold sides, which can greatly improve the robustness of the design and further reduce detrimental contact resistances. Hot-side tubes can be made of ceramic to eliminate issues with coatings and electrical shorting to the base metal. Cold-side tubes can be ceramic as well in order to reduce the number of different parts. Use of ceramic heat exchanger tubes would also reduce axial and radial thermal expansion. Radial thermal expansion issues are also reduced by using smaller diameter tubes. In certain other embodiments, there are no springs at the ends of the rows of couples.

Multiple small diameter tubes can be used for the hot-side tubes, the cold-side tubes, or both which can allow for design flexibility in terms of package space and voltage/current split. Tubes can be connected in series with one another for higher voltage and/or in parallel with one another for redundancy. These tubes and the shunts can still take advantage of beneficial hoop stress to improve thermal contact, but would have fewer TE elements in parallel electrical communication with one another. Sufficient smaller diameter tubes can be used to maintain appropriate pressure drop.

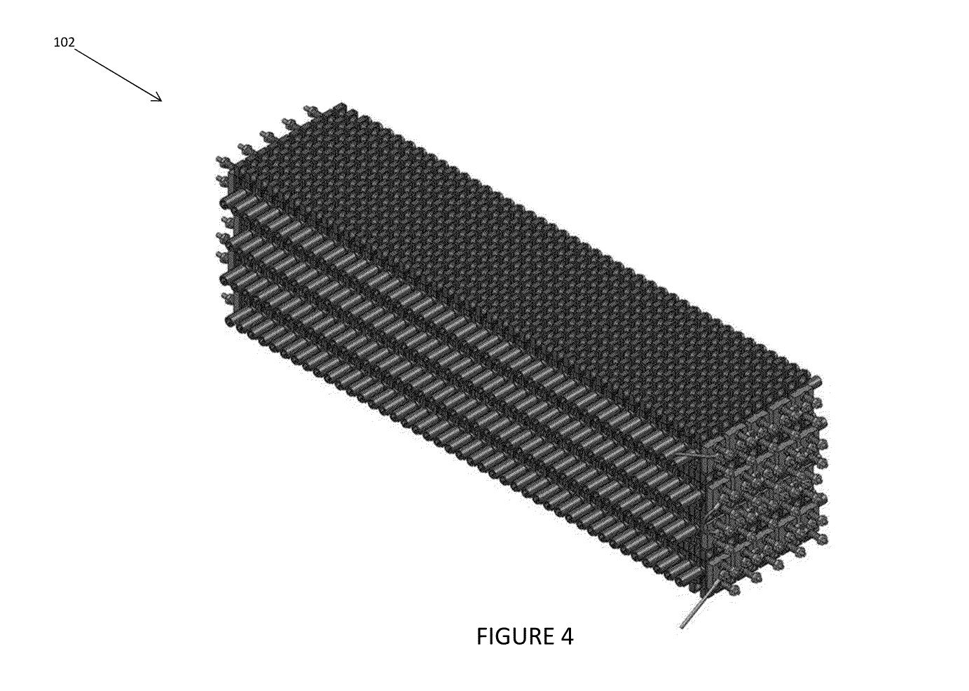

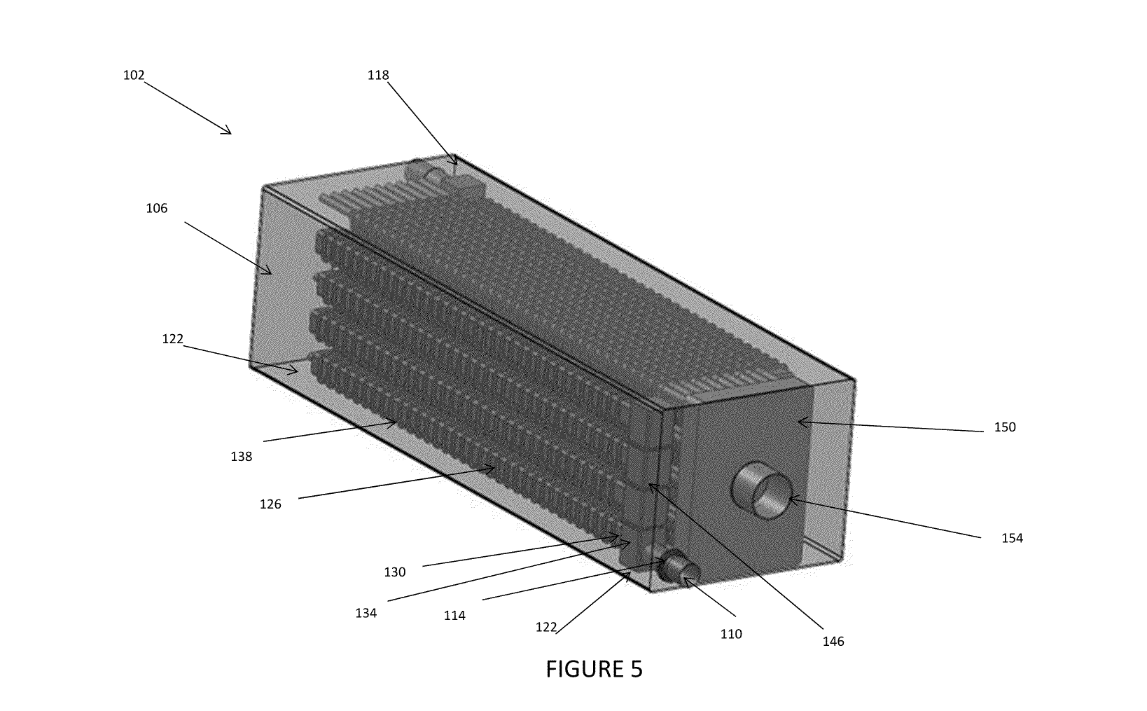

FIG. 4 schematically illustrates the example TE system 10 shown in FIGS. 1A-1C incorporated into a full-scale example TEG system 102 in accordance with certain embodiments described herein. The example TE systems of FIGS. 2A-2C and 3A-3C can also be incorporated into a full-scale example TEG system 102 as shown in FIG. 4. FIG. 5 schematically illustrates an example outer housing 106 on the TEG system 102 of FIG. 4 in accordance with certain embodiments described herein. In some embodiments, this outer housing 106 provides a hermetic enclosure for the TE system 102 so that it can operate in an oxygen-free environment. Any of the example TE systems 10 described herein can comprise a housing 106 containing a first plurality of thermoelectric elements and the second plurality of thermoelectric elements in a hermetically-sealed environment. Such a TE system 10 can further comprise a hermetically-sealed environment substantially free of oxygen.

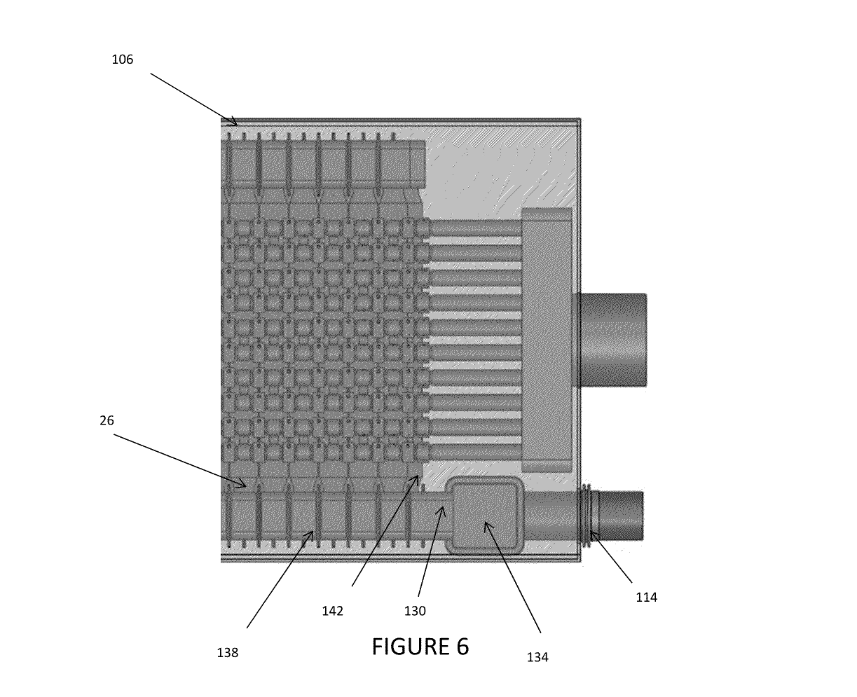

FIGS. 5 and 6 schematically illustrate example hot and cold end or side headers (e.g., manifolds) in accordance with certain embodiments described herein. In some embodiments, at least one of the hot-side headers and the cold-side headers comprises one or more bellows to allow relative movement among the tubes and/or conduits, while in other embodiments, no bellows are used. Each horizontally extending header can be in fluid communication with a plurality of TE systems 10 as described herein and each vertically extending header can be in fluid communication with a plurality of the horizontally-extending headers (e.g., four as shown in FIG. 5). At least one vertically extending header can comprise at least one bellows to allow thermal expansion movement. In some embodiments, there are only two hot-side feedthroughs (e.g., inlet and outlet ports) through the hermetic enclosure (e.g., housing 106). Example ports are shown in more detail in FIG. 6. At least one bellows at the hot entrance/exit from the hermetic enclosure provides thermal expansion mismatch between the hot-side headers and the cold hermetic shell. The cold-side manifold 150 shown in FIGS. 5 and 6 can comprise a tube manifold plate for a shell and tube heat exchanger. Certain embodiments do not include a bellows between the cold-side manifold entrance/exit 154 and the hermetic shell or housing 106 because they are at similar temperatures and can be assumed to have similar thermal expansion rates. If there is a difference in thermal expansion due to the need of using particular high or low thermal expansion material, at least one bellows feedthrough can be added on the cold-side manifold 150 as well.

In some embodiments, as illustrated in FIGS. 5 and 6, the thermoelectric system 102 or TE system 10 further comprises at least one hot-side port 110 (e.g., feedthrough) in fluidic communication with the plurality of hot-side conduits 26. The at least one hot-side port 110 of certain embodiments can comprise at least one bellows 114 mechanically coupled to the housing 106, while other embodiments do not comprise such bellows.

In certain embodiments, as illustrated in FIGS. 5 and 6, the plurality of hot-side conduits 26 is in fluidic communication with an inlet hot-side manifold 118 and an outlet hot-side manifold 122. At least one of the inlet hot-side manifold 118 and the outlet hot-side manifold 122 comprises a plurality of first manifold sub-sections 126. Each first manifold sub-section 126 of the plurality of first manifold sub-sections 126 is in fluidic communication with a corresponding set of the hot-side conduits 142. At least one second manifold sub-section 134 is in fluidic communication with each first manifold sub-section 126 of the plurality of first manifold sub-sections 126.

In certain embodiments, each first manifold sub-section 126 comprises a plurality of bellows 138. Each bellows of the plurality of bellows 138 is positioned between adjacent hot-side conduits 26 of the corresponding set of the hot-side conduits 142. In certain embodiments, the at least one second manifold sub-section 134 comprises one or more bellows 146. Each bellows of the one or more bellows 146 is positioned between adjacent first manifold sub-sections 126 of the plurality of first manifold sub-sections 126. In some embodiments, the plurality of cold-side conduits 14 are in fluidic communication with an inlet cold-side manifold (not shown) and an outlet cold-side manifold 150. In certain embodiments, the manifold sub-sections do not comprise bellows.

FIGS. 7A-7C schematically illustrate examples compression structures 160 of the TE systems 10 in accordance with certain embodiments described herein. Each compression structure 160 of the plurality of compression structures 160 is configured to keep the plurality of thermoelectric elements 46 of at least one thermoelectric stack of the plurality of thermoelectric stacks 42 under compression. In certain embodiments, each compression structure 160 of the plurality of compression structures 160 is configured to apply a compressive force along the third direction to the at least one thermoelectric stack. For example, each hot-side conduit of the plurality of hot-side conduits 26 is in thermal communication with two thermoelectric stacks of the plurality of thermoelectric stacks 42, and each compression structure 160 of the plurality of compression structures 160 is configured to keep the plurality of thermoelectric elements 46 of the two thermoelectric stacks under compression. The compression structures 160 can also aid in lowering interfacial resistances if non-rigid bonds are used between the TE elements and the shunts.

In some embodiments, as shown in FIGS. 7A-7C, the compression structures 160 can comprise one or more compression plates 158 that are attached or coupled to the ends of each set of cold-side tubes and/or conduits. The compression structures 160 can comprise one or more bolts 170 and one or more springs 174 configured to keep the TE elements compressed in the direction of electrical current flow and to prevent the TE elements from going into detrimental tension during operation. For example, as illustrated in FIGS. 1A-1C, in certain embodiments, each compression structure 160 comprises a first plate 178 and a second plate 182 on opposite ends of the at least one thermoelectric stack 42, at least one bolt 170 (e.g., rod) extending at least partially through each of the first plate 178 and the second plate 182, and at least one spring 174 configured to force at least one of the first plate 178 and the second plate 182 towards the other so as to compress the at least one thermoelectric stack 42. In certain embodiments, the compression structures do not comprise springs.

The compression plates 158 can be made of various materials (e.g., stainless steel (SST)) and can have a copper portion 162 that connects at least two rows of TE elements 46. The SST may be used to provide extra strength to the compression plate or system. In some embodiments, flexible jumpers 166 further connect the rows of TE elements 46 electrically. In certain embodiments, the compression structures 160 of the plurality of compression structures 160 are separated from one another as illustrated in FIGS. 7A-7C. For example, the compression plates 158 can be separated from one another to have more TE element rows in series electrical communication with one another to generate or produce higher voltages, power and/or current. This compression plate separation also can prevent over-constraining the cold tubes.

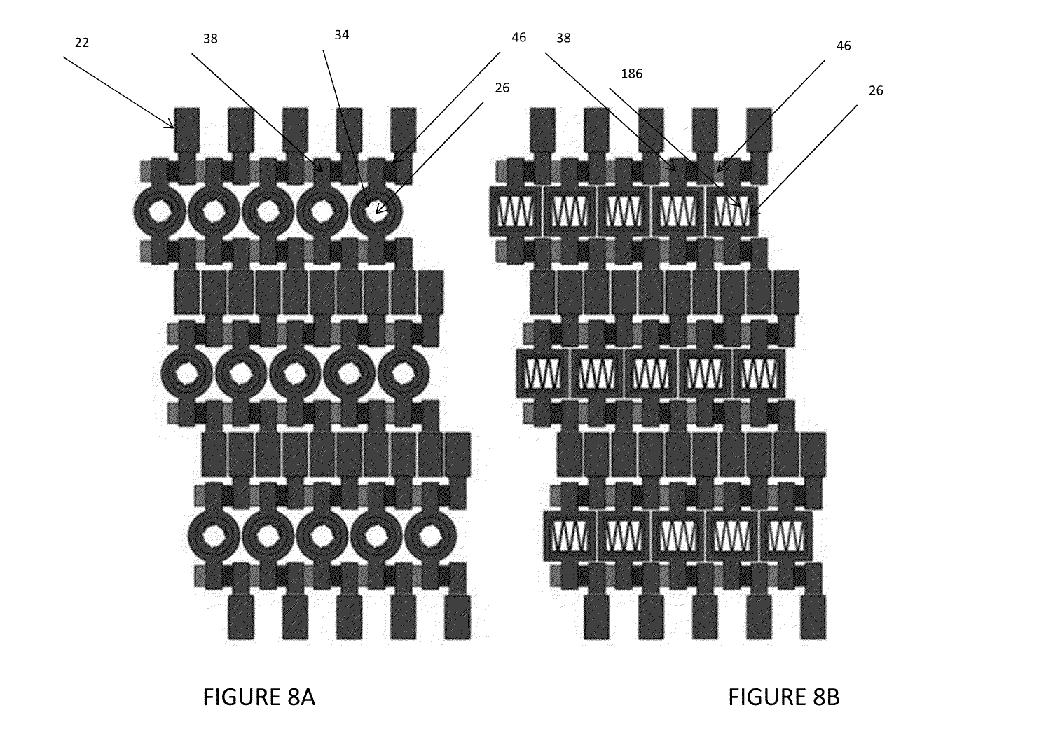

FIGS. 8A-8B schematically illustrate example heat transfer enhancements used with the hot-side conduits 26 or cold-side conduits 14. For example, as shown in FIGS. 8A-8B, the hot-side tubes 34 can be cylindrical with a plurality of extended surfaces 186 (e.g., fins, ribs, rifling) configured to facilitate heat transfer between the tube 34 and the working fluid flowing through the tube 34. Similarly, the cold-side tubes 18 can be cylindrical with a plurality of extended surfaces (e.g., fins, ribs, rifling) configured to facilitate heat transfer between the tube 18 and the working fluid flowing through the tube 18. While illustrated as having cylindrical cross-sections in some embodiments, the conduits 26, 14 and/or tubes 34, 18 can comprise triangular, square, polygonal or other various-shaped cross-sections in a plane perpendicular to the axial direction. For example, they also can have a rectangular cross section, which may provide better space utilization and provide a better opportunity to increase heat transfer surface area with fins within the conduit to improve hot-side heat transfer, cold-side heat transfer, or both. Additionally, the conduits 26, 14 can have the same or different shaped cross-sections relative to the tubes 34, 18.

Hot shunts 38 can encircle the hot-side conduits 26 (to take advantage of hoop stress) as illustrated in FIG. 8A and/or they can be bonded to at least one side of the conduits 26. For example, each hot-side conduit 26 of the TE systems described herein can comprise a tube 34 extending along the second direction and have a circular or rectangular cross-section in a plane perpendicular to the second direction. In certain embodiments, each hot-side conduit 26 further comprises a plurality of hot-side shunts 38 in thermal communication with the tube 34, each hot-side shunt of the plurality of hot-side shunts 38 extending around a cross-sectional perimeter of the tube 34. Similarly, cold shunts 22 can encircle the cold-side conduits 14 (to take advantage of hoop stress) and/or they can be bonded to at least one side of the conduits 14. For example, each cold-side conduit 14 of the TE systems described herein can comprise a tube 18 extending along the first direction and have a circular or rectangular cross-section in a plane perpendicular to the first direction. In certain embodiments each cold-side conduit 14 further comprises a plurality of cold-side shunts 22 in thermal communication with the tube 18, each cold-side shunt of the plurality of cold-side shunts 22 extending around a cross-sectional perimeter of the tube 18.

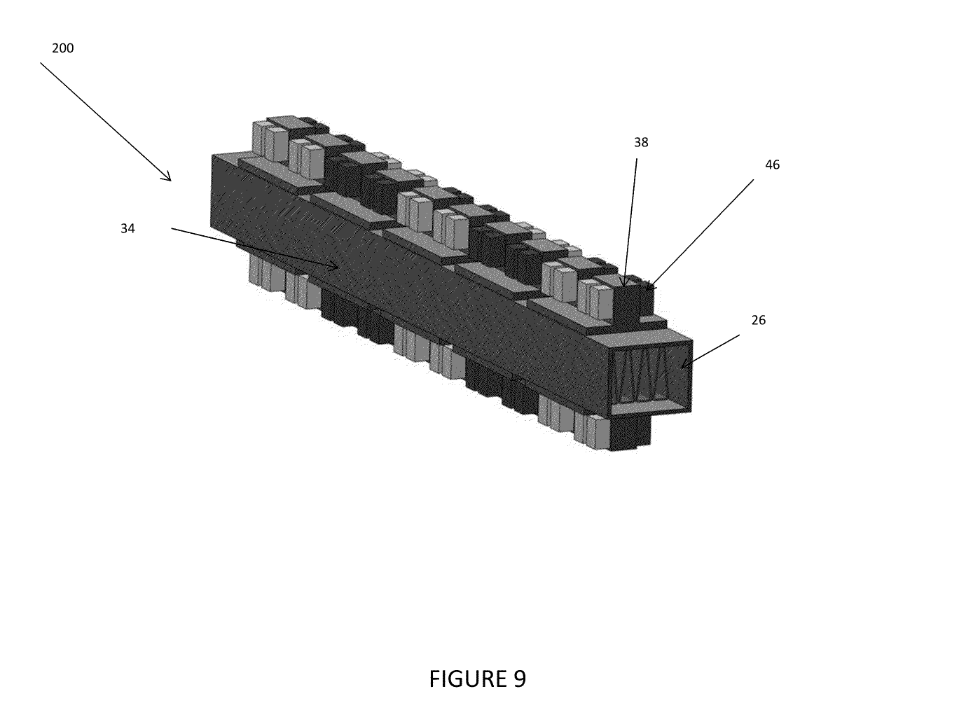

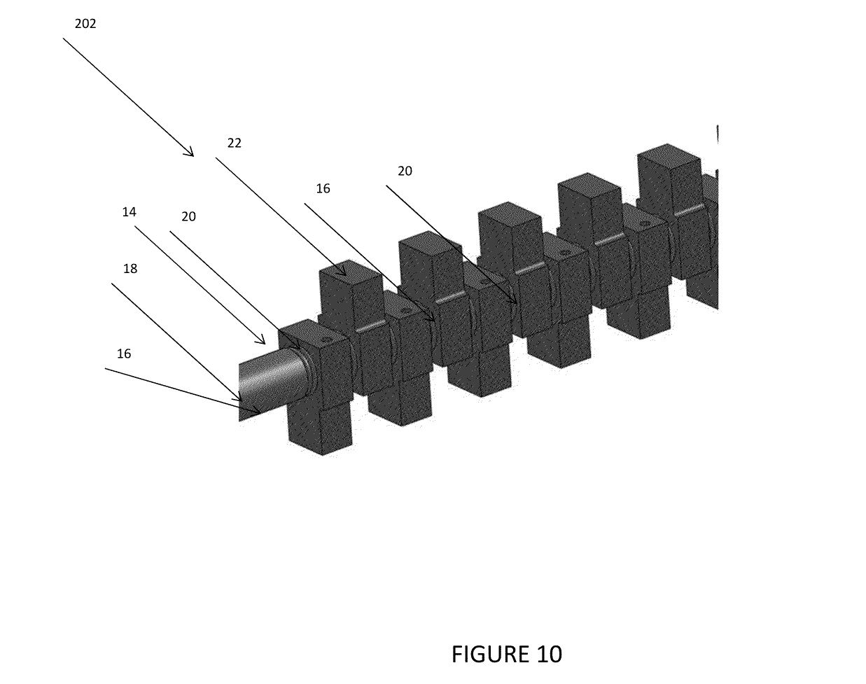

FIG. 9 schematically illustrates an example hot-side tube and/or conduit subassembly 200 that has the hot-side shunts 38 bonded to two sides of the hot-side tube 34. In certain embodiments, each hot-side conduit 26 further comprises a plurality of hot-side shunts 38 in thermal communication with the hot-side tube 34, each hot-side shunt of the plurality of hot-side shunts 38 bonded to a surface of the tube 34.

In some embodiments, as schematically illustrated in FIG. 10, a cold-side conduit 14 comprises a plurality of cold-side shunts 22 and a plurality of cold-side tube portions 16 in thermal communication with the plurality of cold-side shunts 22. Adjacent cold-side shunts of the plurality of cold-side shunts 22 are mechanically coupled to one another by a corresponding cold-side tube portion of the plurality of cold-side tube portions 16. Cold-side tube portions 16 can comprise a bellows 20 on one or both ends of the cold-side tube portion, with the bellows mechanically coupled to a cold-side shunt. In some embodiments, the use of cold-sided tubes with bellows can be used in place of cold-side tube end bellows at one or more manifolds, while in certain other embodiments, no cold-side tube end bellows are used. In some embodiments, cold-side conduits and cold-side shunts are attached such that the cold-side shunts can float on thermal grease between the cold-side shunt and the cold-side tube. In some embodiments, each cold-side conduit 14 comprises a cold-side tube 18 and a plurality of cold-side shunts 22 in thermal communication with the cold-side tube 18 and configured to slide along the cold-side tube 18.

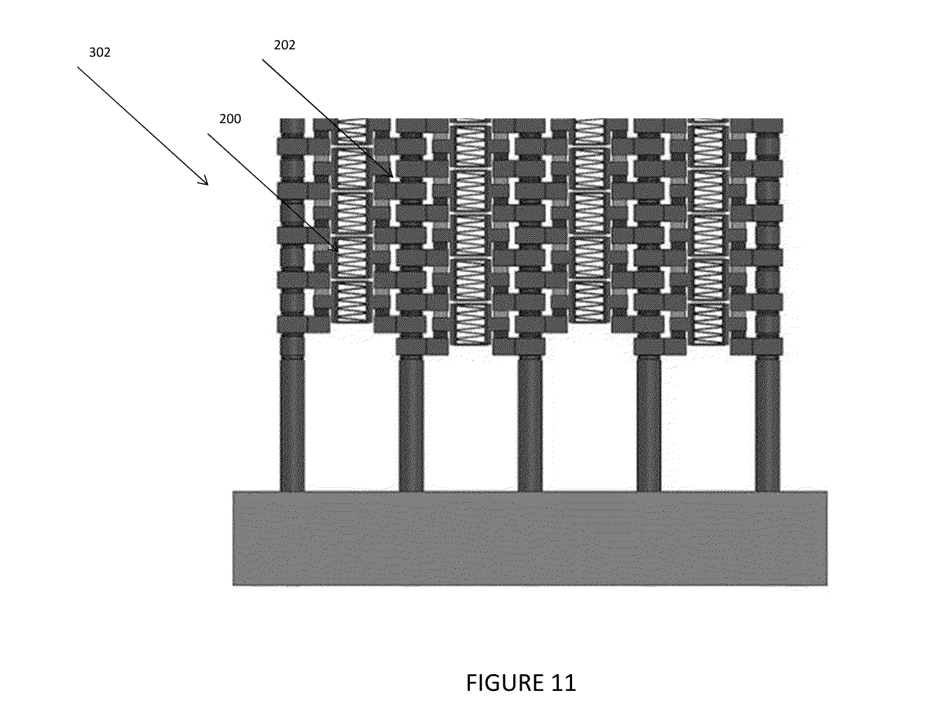

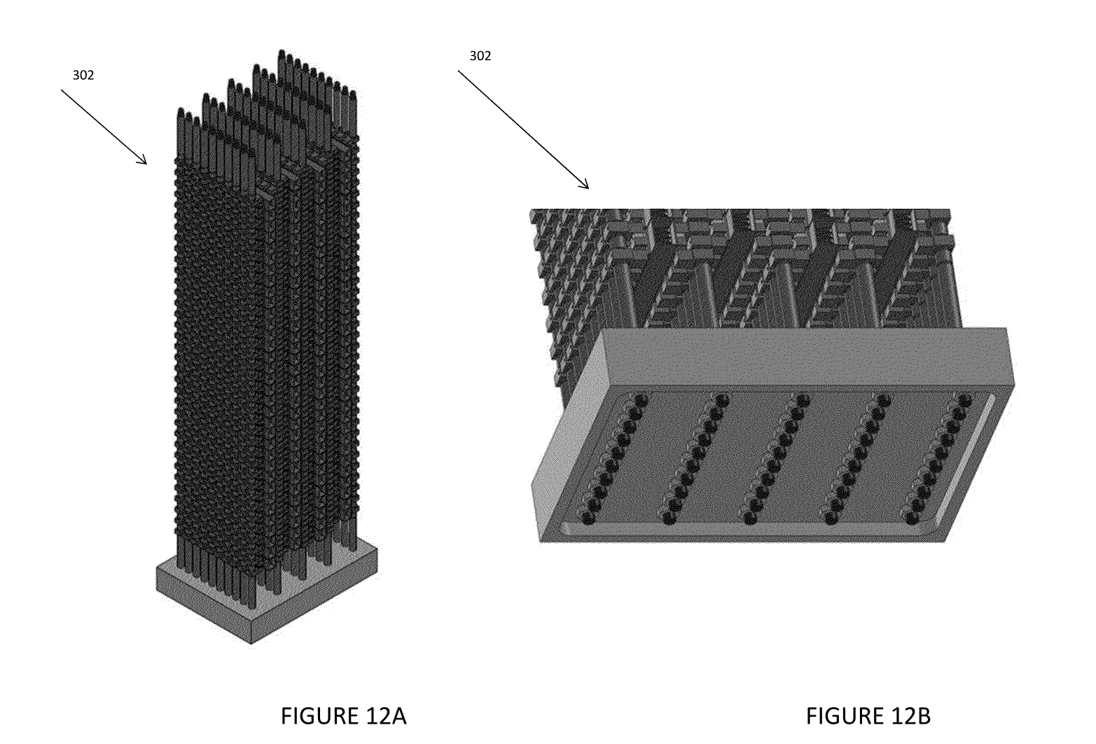

FIGS. 11, 12A, and 12B schematically illustrate example interim structures during the fabrication of a TE system 302 in accordance with certain embodiments described herein. The manufacturing steps of such TE systems described herein can include one or more of the following:

1. Constructing hot-side tubes with hot-side shunts rigidly bonded to the hot-side tubes with TE elements attached as shown in FIG. 9 and FIG. 11.

2. Constructing cold-side tubes with cold-side shunts attached (cold-side shunts can either float on thermal grease or can be rigidly bonded to a bellowed cold-side tube as shown in FIG. 10 or 11).

3. Pre-tin TE elements and cold-side shunts

4. Stack hot-side tubes and cold-side tubes, compress, and place in a reflow oven to flow solder between the cold-side shunts and TE elements (see FIG. 11 and FIGS. 12A-12B).

As described herein, in certain embodiments, the criss-cross nature of the tubes, conduits, and/or electrical current flow allows axial thermal expansion of the hot-side tubes to move the cold-side tubes, while the movement is absorbed (e.g., by bellows at the manifolds). In some embodiments, such movement does not take place in the direction of electrical compressive forces. TE couples or stacks and compressed in the direction of flow in the cold-side tubes, which have little thermal expansion movement. In some embodiments, if the cold-side tubes extend in a direction perpendicular to electrical current flow, radial thermal expansion of the hot-side tubes can also be absorbed (e.g., by the cold end bellows) as well as axial thermal expansion as discussed above.

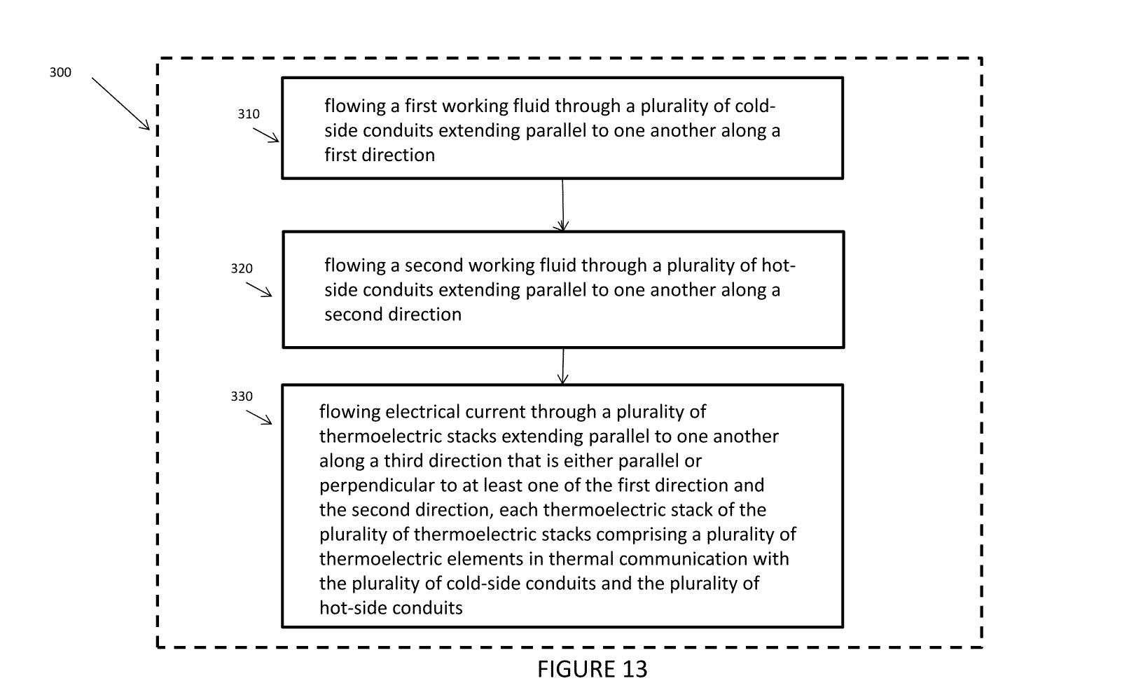

FIG. 13 is a generalized block flowchart of an example method 300 of managing thermal expansion of a TE system 10 in accordance with certain embodiments described herein. The TE system 10 can comprise a plurality of cold-side conduits 14 extending parallel to one another along a first direction, a plurality of hot-side conduits 26 extending parallel to one another along a second direction. Each cold-side conduit of the plurality of cold-side conduits 14 can comprise a cold-side tube 18 and a plurality of cold-side shunts 22 in thermal communication with the cold-side tube 18. Each hot-side conduit of the plurality of hot-side conduits 26 can comprise a hot-side tube 34 and a plurality of hot-side shunts 38 in thermal communication with the hot-side tube 34. While the following description of the example method 300 includes reference to the structures shown in FIGS. 1-12 and described above, the method 300 can be practiced using other structures, components, and configurations.

In an operational block 310, the method 300 comprises flowing a first working fluid through a plurality of cold-side conduits extending parallel to one another along a first direction. In an operational block 320, the method 300 further comprises flowing a second working fluid through a plurality of hot-side conduits extending parallel to one another along a second direction. In an operational block 330, the method 300 further comprises flowing electrical current through a plurality of thermoelectric stacks extending parallel to one another along a third direction that is either parallel or perpendicular to at least one of the first direction and the second direction, each thermoelectric stack of the plurality of thermoelectric stacks comprising a plurality of thermoelectric elements in thermal communication with the plurality of cold-side conduits and the plurality of hot-side conduits.

In some embodiments, the third direction is parallel to the first direction. In certain embodiments, the third direction is perpendicular to the first direction and perpendicular to the second direction.

In some embodiments, the method 300 further comprises isolating the plurality of thermoelectric stacks 42 from severe shock and vibration. In some embodiments, each cold-side conduit of the plurality of cold-side conduits 14 is in fluidic communication with an inlet cold-side manifold 78 and an outlet cold-side manifold 82. Each cold-side conduit of the plurality of cold-side conduits 14 comprises at least a first bellows portion 86 mechanically coupled to the inlet cold-side manifold 78 and a second bellows portion 90 mechanically coupled to the outlet cold-side manifold 82. In certain embodiments, no bellows portions are used on at least one of the cold-side manifold or the hot-side manifold.

In some embodiments, the method 300 further comprises keeping the plurality of thermoelectric elements 46 under compression. The method 300 can further comprise rigidly connecting the hot-side shunts 38 with the hot-side tubes 34 and the cold-side shunts 22 with the cold-side tubes 18.

Although certain configurations and examples are disclosed herein, the subject matter extends beyond the examples in the specifically disclosed configurations to other alternative configurations and/or uses, and to modifications and equivalents thereof. Thus, the scope of the claims appended hereto is not limited by any of the particular configurations described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain configurations; however, the order of description should not be construed to imply that these operations are order dependent. Additionally, the structures, systems, and/or devices described herein may be embodied as integrated components or as separate components. For purposes of comparing various configurations, certain aspects and advantages of these configurations are described. Not necessarily all such aspects or advantages are achieved by any particular configuration. Thus, for example, various configurations may be carried out in a manner that achieves or optimizes one advantage or group of advantages as taught herein without necessarily achieving other aspects or advantages as may also be taught or suggested herein.

Discussion of the various configurations herein has generally followed the configurations schematically illustrated in the figures. However, it is contemplated that the particular features, structures, or characteristics of any configurations discussed herein may be combined in any suitable manner in one or more separate configurations not expressly illustrated or described. In many cases, structures that are described or illustrated as unitary or contiguous can be separated while still performing the function(s) of the unitary structure. In many instances, structures that are described or illustrated as separate can be joined or combined while still performing the function(s) of the separated structures.

Various configurations have been described above. Although the invention has been described with reference to these specific configurations, the descriptions are intended to be illustrative and are not intended to be limiting. Various modifications and applications may occur to those skilled in the art without departing from the true spirit and scope of the invention as defined in the appended claims.

What is claimed is:

1. A thermoelectric system comprising:
a plurality of cold-side conduits extending parallel to one another along a first direction and configured to have a first working fluid flowing therethrough, each cold-side conduit of the plurality of cold-side conduits comprising a cold-side tube and a plurality of cold-side shunts in thermal communication with the cold-side tube;
a plurality of hot-side conduits extending parallel to one another along a second direction and configured to have a second working fluid flowing therethrough, the second direction perpendicular to the first direction, each hot-side conduit of the plurality of hot-side conduits comprising a hot-side tube and a plurality of hot-side shunts in thermal communication with the hot-side tube; and
a plurality of thermoelectric stacks, each thermoelectric stack of the plurality of thermoelectric stacks comprising a plurality of thermoelectric elements, a first plurality of cold-side shunts of a first cold-side conduit, a first hot-side shunt of a first hot-side conduit, and a second hot-side shunt of a second hot-side conduit, each thermoelectric stack of the plurality of thermoelectric stacks extending along a third direction and configured to have electrical current flow through the thermoelectric stack along the third direction.

2. The thermoelectric system of claim 1, wherein each hot-side conduit of the plurality of hot-side conduits is in thermal communication with two thermoelectric stacks of the plurality of thermoelectric stacks.

3. The thermoelectric system of claim 1, wherein the third direction is parallel to the first direction.

4. The thermoelectric system of claim 1, wherein the third direction is perpendicular to the first direction and perpendicular to the second direction.

5. The thermoelectric system of claim 1, wherein each cold-side conduit of the plurality of cold-side conduits is in fluidic communication with an inlet cold-side manifold and an outlet cold-side manifold, wherein each cold-side conduit of the plurality of cold-side conduits comprises at least a first bellows portion mechanically coupled to the inlet cold-side manifold and a second bellows portion mechanically coupled to the outlet cold-side manifold.

6. The thermoelectric system of claim 1, wherein each cold-side shunt of the plurality of cold-side shunts comprises at least one hole configured to allow a thermally conductive medium to be applied between the cold-side shunt and the cold-side tube

7. The thermoelectric system of claim 1, further comprising a housing containing first plurality of thermoelectric elements and the second plurality of thermoelectric elements in a hermetically-sealed environment.

8. The thermoelectric system of claim 7, wherein the hermetically-sealed environment is substantially free of oxygen.

9. The thermoelectric system of claim 7, further comprising at least one hot-side port in fluidic communication with the plurality of hot-side conduits, the at least one hot-side port comprising at least one bellows mechanically coupled to the housing.

10. The thermoelectric system of claim 1, wherein the plurality of hot-side conduits is in fluidic communication with an inlet hot-side manifold and an outlet hot-side manifold, wherein at least one of the inlet hot-side manifold and the outlet hot-side manifold comprises:
a plurality of first manifold sub-sections, each first manifold sub-section of the plurality of first manifold sub-sections in fluidic communication with a corresponding set of the hot-side conduits; and
at least one second manifold sub-section in fluidic communication with each first manifold sub-section of the plurality of first manifold sub-sections.

11. The thermoelectric system of claim 10, wherein each first manifold sub-section comprises a plurality of bellows, each bellows of the plurality of bellows positioned between adjacent hot-side conduits of the corresponding set of the hot-side conduits.

12. The thermoelectric system of claim 10, wherein the at least one second manifold sub-section comprises one or more bellows, each bellows of the one or more bellows positioned between adjacent first manifold sub-sections of the plurality of first manifold sub-sections.

13. The thermoelectric system of claim 1, wherein the plurality of cold-side conduits are in fluidic communication with an inlet cold-side manifold and an outlet cold-side manifold.

14. The thermoelectric system of claim 1, further comprising a plurality of compression structures, each compression structure of the plurality of compression structures configured to keep the plurality of thermoelectric elements of at least one thermoelectric stack of the plurality of thermoelectric stack under compression.

15. The thermoelectric system of claim 14, wherein each compression structure of the plurality of compression structures is configured to apply a compressive force along the third direction to the at least one thermoelectric stack.

16. The thermoelectric system of claim 14, wherein each hot-side conduit of the plurality of hot-side conduits is in thermal communication with two thermoelectric stacks of the plurality of thermoelectric stacks, and each compression structure of the plurality of compression structures is configured to keep the plurality of thermoelectric elements of the two thermoelectric stacks under compression.

17. The thermoelectric system of claim 14, wherein the compression structures of the plurality of compression structures are separated from one another.

18. The thermoelectric system of claim 14, wherein each compression structure comprises a first plate and a second plate on opposite ends of the at least one thermoelectric stack, at least one rod extending at least partially through each of the first plate and the second plate, and at least one spring configured to force at least one of the first plate and the second plate towards the other so as to compress the at least one thermoelectric stack.

19. The thermoelectric system of claim 1, wherein each hot-side conduit comprises a tube extending along the first direction and having a circular, rectangular or polygonal cross-section in a plane perpendicular to the first direction.

20. The thermoelectric system of claim 19, wherein the tube comprises a plurality of extended surfaces configured to be in thermal communication with the first working fluid.

21. The thermoelectric system of claim 19, wherein each hot-side, conduit further comprises a plurality of hot-side shunts in thermal communication with the tube, each hot-side shunt of the plurality of hot-side shunts extending around a cross-sectional perimeter of the tube.

22. The thermoelectric system of claim 19, wherein each hot-side conduit further comprises a plurality of hot-side shunts in thermal communication with the tube, each hot-side shunt of the plurality of hot-side shunts bonded to a surface of the tube.

23. The thermoelectric system of claim 1, wherein each cold-side conduit comprises a plurality of cold-side shunts and a plurality of bellowed cold-side tube portions in thermal communication with the plurality of cold-side shunts, wherein adjacent cold-side shunts of the plurality of cold-side shunts are mechanically coupled to one another by a corresponding bellowed cold-side tube portion of the plurality of bellowed cold-side tube portions.

24. The thermoelectric system of claim 1, wherein each cold-side conduit comprises a cold-side tube and a plurality of cold-side shunts in thermal communication with the cold-side tube and configured to slide along the cold-side tube.

25. A thermoelectric system comprising:
a plurality of cold-side heat exchangers extending parallel to one another along a first direction, each cold-side heat exchanger of the plurality of cold-side heat exchangers comprising a cold-side member and a plurality of cold-side shunts in thermal communication with the cold-side member;
a plurality of hot-side heat exchangers extending parallel to one another along a second direction, the second direction perpendicular to the first direction, each hot-side heat exchanger of the plurality of hot-side heat exchangers comprising a hot-side member and a plurality of hot-side shunts in thermal communication with the hot-side member; and
a plurality of thermoelectric stacks, each thermoelectric stack of the plurality of thermoelectric stacks comprising a plurality of thermoelectric elements, a first plurality of cold-side shunts of a first cold-side heat exchanger, a first hot-side shunt of a first hot-side heat exchanger, and a second hot-side shunt of a second hot-side heat exchanger, each thermoelectric stack of the plurality of thermoelectric stacks extending along a third direction and configured to have electrical current flow through the thermoelectric stack along the third direction.

26. The thermoelectric system of claim 25, wherein at least one of the cold-side member and the hot-side member comprises a tube.

27. A method of managing thermal expansion during operation of a thermoelectric system, the method comprising:
flowing a first working fluid through a plurality of cold-side conduits extending parallel to one another along a first direction;
flowing a second working fluid through a plurality of hot-side conduits extending parallel to one another along a second direction; and
flowing electrical current through a plurality of thermoelectric stacks extending parallel to one another along a third direction that is either parallel or perpendicular to at least one of the first direction and the second direction, each thermoelectric stack of the plurality of thermoelectric stacks comprising a plurality of thermoelectric elements in thermal communication with the plurality of cold-side conduits and the plurality of hot-side conduits.

28. The method of claim 27, wherein the third direction is parallel to the first direction.

29. The method of claim 27, wherein the third direction is perpendicular to the first direction and perpendicular to the second direction.

30. The method of claim 27, further comprising isolating the plurality of thermoelectric stacks from severe shock and vibration.

31. The method of claim 30, wherein each cold-side conduit of the plurality of cold-side conduits is in fluidic communication with an inlet cold-side manifold and an outlet cold-side manifold, wherein each cold-side conduit of the plurality of cold-side conduits comprises at least a first bellows portion mechanically coupled to the inlet cold-side manifold and a second bellows portion mechanically coupled to the outlet cold-side manifold.

32. The method of claim 27, further comprising keeping the plurality of thermoelectric elements under compression.

33. The method of claim 27, wherein the hot-side conduits comprise hot-side tubes and the cold-side conduits comprise cold-side tubes, the method further comprising rigidly connecting hot-side shunts with the hot-side tubes and rigidly connecting cold-side shunts with the cold-side tubes.
